(19) United States
(12) Patent Application Publication
(10) Pub. No.: US 2020/0105702 A1
(43) Pub. Date: Apr. 2, 2020

(54) BUMP STRUCTURE AND FABRICATION METHOD THEREOF

(71) Applicant: Samsung Electronics Co., Ltd., Suwon-si (KR)

(72) Inventors: Chanho LEE, Hwaseong-si (KR); lnyoung LEE, Yongin-si (KR); Jinkuk BAE, Hwaseong-si (KR); Hyunsoo CHUNG, Hwaseong-si (KR)

(73) Assignee: Samsung Electronics Co., Ltd., Suwon-si (KR)

(21) Appl. No.: 16/394,690

(22) Filed: Apr. 25, 2019

(30) Foreign Application Priority Data
Sep. 28, 2018 (KR) 10-2018-0115951

(51) Int. Cl. H01L 23/00; H01L 21/768

(52) U.S. Cl. CPC H01L 24/17; H01L 24/09; H01L 2224/17505; H01L 21/76873; H01L 24/11

(57) ABSTRACT

Disclosed are bump structures and bump structure fabrication methods. A bump structure including a pad and a bump on a top surface of the pad may be provided. The bump may include an upper bump portion and the lower bump portion, and the lower bump portion may include a pedestal portion in contact with the top surface of the pad and a pillar portion upwardly extending from the pedestal portion. A cross-sectional area of at least a portion of the pedestal portion along a first direction may be greater than a cross-sectional area of the pillar portion along the first direction.

### CROSS-REFERENCE TO RELATED APPLICATION

This U.S. non-provisional application claims priority under 35 U.S.0 § 119 to Korean Patent Application No. 10-2018-0115951, filed on Sep. 28, 2018 in the Korean Intellectual Property Office, the entire contents of which are hereby incorporated by reference.

### BACKGROUND

The present inventive concepts relate to bump structures and/or bump structure fabrication methods, and more particularly, to bump structures in which no seed layer remains and/or fabrication methods for forming such bump structures.

A semiconductor package is provided to implement an integrated circuit chip to be used in electronic products. For example, a semiconductor package is configured such that a semiconductor chip is mounted on a printed circuit board (PCB) and electrically connected to the printed circuit board using bonding wires or bumps.

A bump electrode is a connection terminal to mount a semiconductor chip on a circuit board of an electronic product. A bump electrode protrudes from a semiconductor chip. For example, a large number of bump electrodes are arranged on pads of the semiconductor chip. To accommodate demands for faster speed, higher degree of integration, and multi-functionality of semiconductor devices, the number of bumps tends to increase, and bumps are desired to have improved electrical and/or mechanical characteristics.

### SUMMARY

Some example embodiments of the present inventive concepts provide bump structures in which no seed layer remains and/or fabrication methods forming such bump structures.

Some example embodiments of the present inventive concepts provide a bump structures and/or bump structure fabrication methods in which an undercut phenomenon is avoided.

According to an example embodiment, a bump structure includes a pad and a bump on a top surface of the pad, the bump including an upper bump portion and the lower bump portion, the lower bump portion including a pedestal portion in contact with the top surface of the pad and a pillar portion upwardly extending from the pedestal portion, a cross-sectional area of at least a portion of the pedestal portion along a first direction being greater than a cross-sectional area of the pillar portion along the first direction.

According to an example embodiment, a bump structure includes a pad and a bump on a top surface of the pad, the bump including a pedestal portion in contact with the pad and a body portion upwardly extending from the pedestal portion, a cross-sectional area of at least a portion of the pedestal portion along a first direction being greater than a cross-sectional area of the body portion along the first direction.

According to an example embodiment, a bump fabrication method includes preparing an electronic device having a pad thereon, forming a seed layer on the pad, forming a photosensitive layer pattern on the seed layer to expose a portion of the seed layer, removing the exposed portion of the seed layer to expose a portion of the pad, and forming a bump on the exposed portion of the pad.

Details of some other example embodiments may be included in the description and drawings.

### BRIEF DESCRIPTION OF THE DRAWINGS

FIG. 1 illustrates a cross-sectional view showing a bump structure according to an example embodiment of the present inventive concepts.

FIG. 2 illustrates a flow chart showing a bump structure fabrication method according to an example embodiment of the present inventive concepts.

FIG. 3 illustrates a cross-sectional view showing a process of exposing a pad in the bump structure fabrication method shown in the flow chart of FIG. 2.

FIG. 4 illustrates a cross-sectional view showing a process of forming a seed layer in the bump structure fabrication method shown in the flow chart of FIG. 2.

FIG. 5 illustrates a cross-sectional view showing a process of forming a photosensitive layer in the bump structure fabrication method shown in the flow chart of FIG. 2.

FIG. 6 illustrates a cross-sectional view showing a process of partially exposing a seed layer in the bump structure fabrication method shown in the flow chart of FIG. 2.

FIG. 7A illustrates a cross-sectional view showing a process of partially exposing a pad in the bump structure fabrication method shown in the flow chart of FIG. 2.

FIG. 7B illustrates an enlarged view showing section VIIB of FIG. 7A.

FIG. 8 illustrates a cross-sectional view showing a process of forming a bump in the bump structure fabrication method shown in the flow chart of FIG. 2.

FIG. 9 illustrates a cross-sectional view showing a process of removing a photosensitive layer in the bump structure fabrication method shown in the flow chart of FIG. 2.

FIG. 10 illustrates a cross-sectional view showing a process of removing a seed layer in the bump structure fabrication method shown in the flow chart of FIG. 2.

FIG. 11 illustrates a cross-sectional view showing a process of performing an annealing process in the bump structure fabrication method shown in the flow chart of FIG. 2.

FIG. 12 illustrates a cross-sectional view showing a bump structure according to an example embodiment of the present inventive concepts.

FIG. 13 illustrates a cross-sectional view associated with a process of partially exposing a pad for forming the bump structure illustrated in FIG. 12.

FIG. 14 illustrates a cross-sectional view associated with a process of forming a bump for forming the bump structure illustrated in FIG. 12

FIG. 15 illustrates a cross-sectional view showing a bump structure according to an example embodiment of the present inventive concepts.

FIG. 16 illustrates a cross-sectional view associated with a process of partially exposing a pad for forming the bump structure shown in FIG. 15.

FIG. 17 illustrates a cross-sectional view associated with a process of forming a bump for forming the bump structure shown in FIG. 15.

FIG. 18 illustrates a cross-sectional view showing a bump structure according to some example embodiments of the present inventive concepts.

FIG. 19 illustrates a cross-sectional view associated with a process of forming a bump for forming the bump structure shown in FIG. 18.

FIG. 20 illustrates a cross-sectional view associated with a process of removing a photosensitive layer for forming the bump structure shown in FIG. 18.

FIG. 21 illustrates a cross-sectional view associated with a process of removing a seed layer for forming the bump structure shown in FIG. 18.

### DETAILED DESCRIPTION

The following will now describe some example embodiments of the present inventive concepts with reference to the accompanying drawings. Like reference numerals may indicate like components throughout the description.

While the term “same” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure.

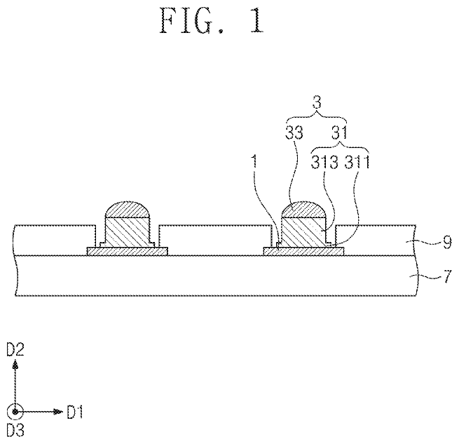

FIG. 1 illustrates a cross-sectional view showing a bump structure according to an example embodiment of the present inventive concepts.

In FIG. 1 and other drawings, a right-left direction may be referred to as a first direction D1, an upward-downward direction may be called a second direction D2, and a perpendicular direction to the first and second directions D1 and D2 may be referred to as a third direction D3. The first direction D1 may also be referred to as a right-left direction. The second direction D2 may also be referred to as an upward-downward direction. The third direction D3 may also be referred to as a front-back direction.

Referring to FIG. 1, an electronic device 7 may be provided. The electronic device 7 may include a semiconductor chip or a substrate. The electronic device 7 may be provided on its top surface with a dielectric layer 9 and a pad 1.

The pad 1 may be provided on the electronic device 7. The pad 1 may include a conductive material. In certain example embodiments, the pad 1 may include aluminum or copper. The pad 1 may electrically connect an inside of the electronic device 7 to an external device. For example, the pad 1 may be electrically connected to internal integrated circuits (not shown) inside the electronic device 7. In this description, the phrase “electrically connected/coupled to” may mean “directly connected/coupled to” or “indirectly connected/coupled through other conductive component to.”

The pad 1 may protrude from the top surface of the electronic device 7, but the present inventive concepts are not limited thereto. For example, the pad 1 may be located at a certain depth from the top surface of the electronic device 7.

The dielectric layer 9 may include a dielectric material. The dielectric layer 9 may protect the electronic device 7. The dielectric layer 9 may have a thickness greater than that of the pad 1. In certain example embodiments, the dielectric layer 9 may cover a portion of the pad 1 and may expose other portion(s) of the pad 1. In some example embodiments, the dielectric layer 9 may entirely expose a top surface of the pad 1. A detailed description thereof will be further discussed below.

A bump 3 may be provided on the pad 1. The bump 3 may include a lower bump portion 31 and an upper bump portion 33. The lower bump portion 31 may include a pedestal portion 311 and a pillar portion 313. In this disclosure, the term “bump structure” refers to a structure including the bump 3 and the pad 1.

The pedestal portion 311 may contact the top surface of the pad 1. The pedestal portion 311 may upwardly extend a certain length from the top surface of the pad 1. In certain example embodiments, the pedestal portion 311 may have a pillar shape substantially perpendicular to the top surface of the pad 1. The pedestal portion 311 may have a cross-sectional area in the first direction D1 equal to or less than that of the pad 1. In this description, the cross-sectional area of the pedestal portion 311 may indicate an area of a surface of the pedestal portion 311 taken along a plane parallel to the first direction D1 and the third direction D3. The pedestal portion 311 may have a circular shape when viewed in a plan view. Thus, the pedestal portion 311 may have a cylindrical shape. In some example embodiments, the pedestal portion 311 may have a triangular shape, a rectangular shape, or any other shape when viewed in plan.

The pillar portion 313 may upwardly extend a certain length from the pedestal portion 311. The pillar portion 313 and the pedestal portion 311 may be formed into a single integral body. The pillar portion 313 may have a height greater than that of the pedestal portion 311. The pillar portion 313 may have a cross-sectional area greater than that of the pedestal portion 311. In this description, the cross-sectional area of the pillar portion 313 may indicate an area of a surface of the pillar portion 313 taken along a plane parallel to the first direction D1 and the third direction D3. The pillar portion 313 may have a cylindrical shape. In such a case, the cross sectional area of the pillar portion 313 may have a circular shape. In some example embodiments, the pillar portion 313 may have a triangular shape, a rectangular shape, or any other shape when viewed in plan.

The lower bump portion 31 may include a conductive material. In certain example embodiments, the lower bump portion 31 may include copper. The present inventive concepts, however, are not limited thereto.

The upper bump portion 33 may be formed on a top surface of the pillar portion 313. In certain example embodiments, the upper bump portion 33 may have a cross-sectional area that increases as approaching the pillar portion 313. In this description, the cross-sectional area of the upper bump portion 33 may indicate an area of the upper bump portion 33 taken along a plane parallel to the first direction D1 and the third direction D3. The upper bump portion 33 and the pillar portion 313 may have the same or substantially similar cross-sectional areas at a location where the upper bump portion 33 meets the pillar portion 313. In certain example embodiments, the upper bump portion 33 may have a hemispherical shape. In some example embodiments, the upper bump portion 33 may have any other shape whose cross-sectional area increases as approaching the pillar portion 313. The upper bump portion 33 may include a conductive material. In certain example embodiments, the upper bump portion 33 may include solder.

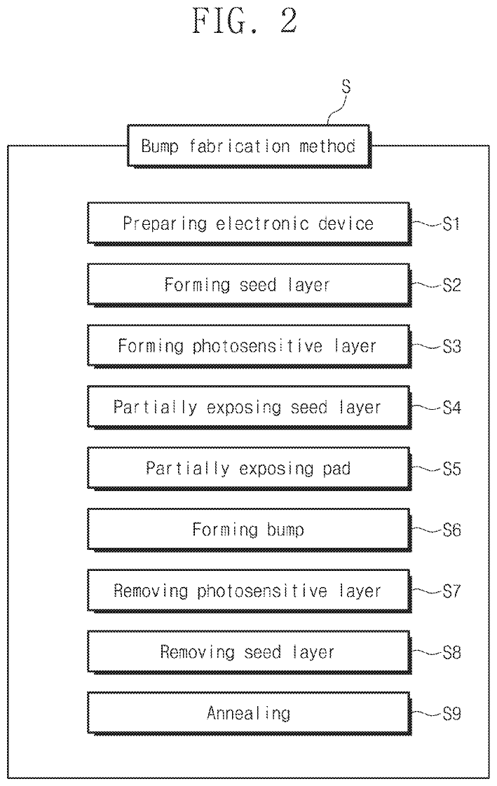

FIG. 2 illustrates a flow chart showing a bump structure fabrication method according to an example embodiment of the present inventive concepts. FIGS. 3 to 11 illustrate cross-sectional views with regard to respective processes of the bump structure fabrication method shown in the flow chart of FIG. 2.

Referring to FIG. 2, a bump structure fabrication method S may include preparing an electronic device (S1), forming a seed layer (S2), forming a photosensitive layer (S3), partially exposing the seed layer (S4), partially exposing a pad (S5), forming a bump (S6), removing the photosensitive layer (S7), removing the seed layer (S8), and annealing (S9).

Referring to FIG. 3, an electronic device 7 may be provided at the process S1. The electronic device 7 may be provided on its top surface 71 with a dielectric layer 9 and/or a pad 1. The dielectric layer 9 may be provided therein with an opening 9h. The dielectric layer 9 may have a top surface 91 higher than a top surface 11 of the pad 1. The top surface 11 of the pad 1 may be partially exposed by the opening 9h of the dielectric layer 9. Of the top surface 11 of the pad 1, a portion exposed by the opening 9h of the dielectric layer 9 may be referred to as a pad exposed surface 111, and other portion not exposed to the opening 9h of the dielectric layer 9 may be referred to as a pad edge surface 113.

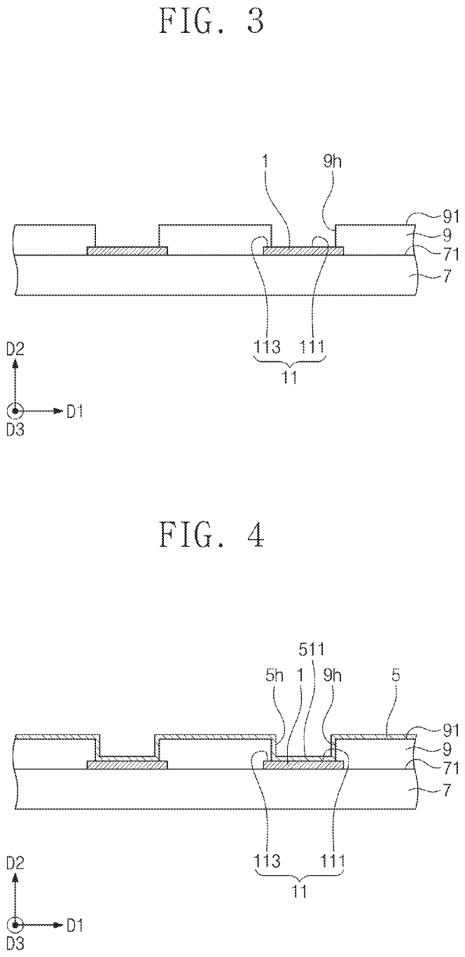

Referring to FIG. 4, at the process S2, a seed layer 5 may be provided on the pad 1 and/or the dielectric layer 9. The seed layer 5 may be conformally formed on the top surface 91 of the dielectric layer 9, a sidewall of the dielectric layer 9 defining the opening 9h, and an entirety or a portion of the top surface 11 of the pad 1. The seed layer 5 formed in the opening 9h may form a recess 5h thereof. The seed layer 5 formed on the pad 1 may have a recessed bottom surface 511 thereof. In certain example embodiments, a deposition process may be performed to form the seed layer 5. The seed layer 5 may include a conductive material. In certain example embodiments, the seed layer 5 may include titanium, titanium tungsten (TiW), or copper. In some example embodiments, the seed layer 5 may include metal different from those mentioned above.

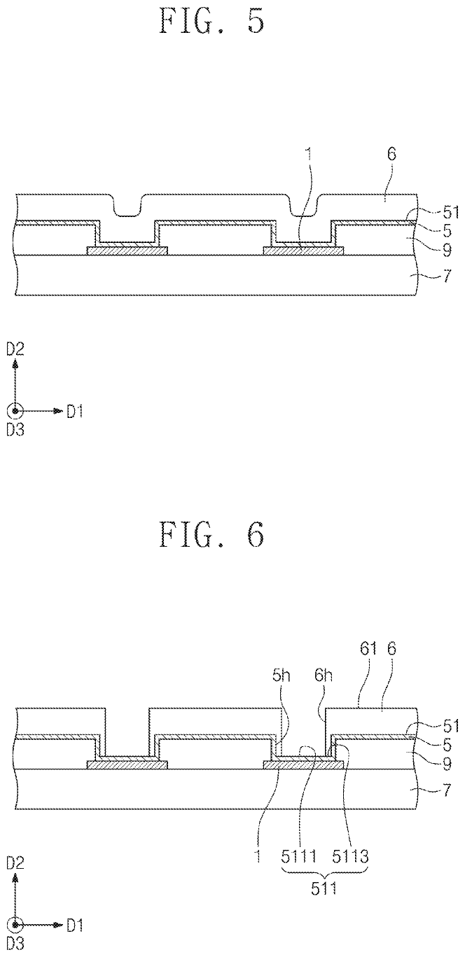

Referring to FIG. 5, at the process S3, a photosensitive layer 6 may be formed on the seed layer 5. For example, the photosensitive layer 6 may be coated on a top surface 51 of the seed layer 5. The photosensitive layer 6 may be coated by a deposition or coating process. The photosensitive layer 6 may include a photoresist material. In certain example embodiments, the photoresist material may include a photosensitive polymer. The photosensitive polymer may include one or more of photosensitive polyimide (PSPI), polybenzoxazole (PBO), phenolic polymer, and benzocyclobutene (BCB) polymer. The present inventive concepts, however, are not limited thereto.

Referring to FIG. 6, the photosensitive layer 6 may be partially removed to form a photosensitivelayer pattern 6′ at the process S4. The partial removal of the photosensitive layer 6 may be performed by exposure and development processes. The photosensitive layer 6 may be removed at a location corresponding to the recessed bottom surface 511 of the seed layer 5. For example, the photosensitive layer 6 at a location corresponding to the recessed bottom surface 511 of the seed layer 5 may be removed from a top surface 61 of the photosensitive layer 6 down to the recessed bottom surface 511 of the seed layer 5 along the D2 direction. The development process may be a positive-tone development (PTD) process or a negative-tone development (NTD) process. The partial removal of the photosensitive layer 6 may form the photosensitivelayer pattern 6′ which expose at least a portion of the recessed bottom surface 511 of the seed layer 5. Of the recessed bottom surface 511 of the seed layer 5, a portion exposed by the photosensitive layer pattern 6′ may be referred to as an exposed surface 5111, and a portion not exposed by the photosensitive layer pattern 6′ may be an edge surface 5113. The partial removal of the photosensitive layer 6 may form the photosensitive layer pattern 6′ an opening 6h thereof. In certain example embodiments, a spacing distance may be provided between a sidewall defining the recess 5h of the seed layer 5 and a sidewall defining the opening 6h of the photosensitive layer pattern 6′. For example, after forming the recess 5h of the seed layer 5, a portion of the photosensitive layer pattern 6′ may cover the sidewall defining the recess 5h of the seed layer 5. Therefore, the recess 5h of the seed layer 5 shown in FIG. 4 may be smaller than the opening 6h of the photosensitive layer pattern 6′ shown in FIG. 6.

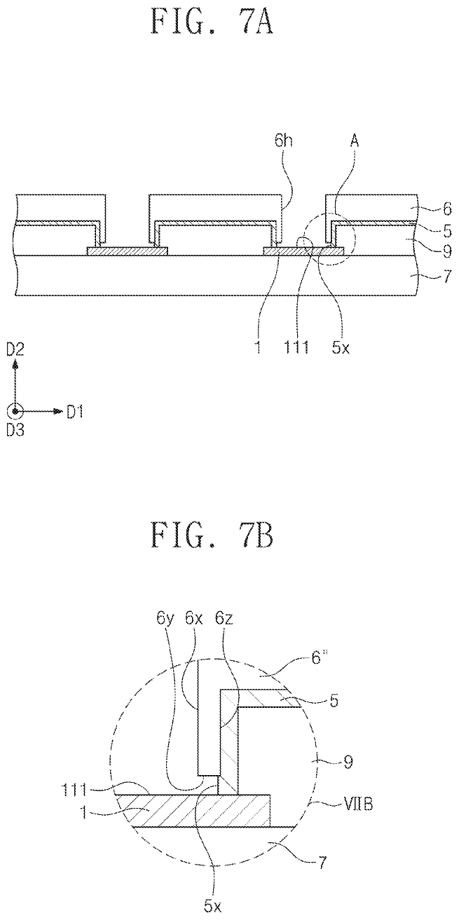

Referring to FIG. 7A, at the process S5, the seed layer 5 may be removed on the pad 1. An etching process may be performed to remove a portion of the seed layer 5. In certain example embodiments, the etching process may include a wet etching process. The pad exposed surface 111 may be exposed again when the portion of the seed layer 5 is removed on the pad 1. The partial removal of the seed layer 5 on the pad 1 may expose a lateral surface 5x positioned on a lower portion of the seed layer 5. The etching process may remove a lowermost portion of the photosensitive layer pattern 6′ to form a modified photosensitive layer 6″.

Referring to FIG. 7B, the exposed lateral surface 5x and the pad exposed surface 111 may be substantially perpendicular to each other. In some example embodiments, the exposed lateral surface 5x may have various shapes which will be discussed below, and thus the exposed lateral surface 5x and the pad exposed surface 111 may not be perpendicular to each other. The modified photosensitive layer pattern 6″ may have a lowermost surface 6y. The lowermost surface 6y of the modified photosensitive layer pattern 6″ may be substantially parallel to the pad 1. Thus, the lowermost surface 6y and the exposed lateral surface 5x may be substantially perpendicular to each other. In some example embodiments, the lowermost surface 6y and the exposed lateral surface 5x may not be perpendicular to each other. The modified photosensitive layer pattern 6″ may have a lateral surface 6x and an inner surface 6z that are substantially perpendicular to the lowermost surface 6y. In certain example embodiments, the exposed lateral surface 5x may be located further in a direction opposite to the first direction D1 than the inner surface 6z. In some example embodiments, the exposed lateral surface 5x may be positioned on the same plane as the inner surface 6z, or may be positioned differently from the inner surface 6z along the first direction D1. The position and shape of the exposed lateral surface 5x may depend on a time duration of the etching process and on an amount and kind of material used for the etching process.

Referring to FIG. 8, at the process S6, a bump 3 may be formed on the pad exposed surface 111. The bump 3 may be formed by an electroplating process in which the seed layer 5 is used as an electrode. The bump 3 may include a lower bump portion 31 and an upper bump 33. The lower bump portion 31 and the upper bump portion 33 may be formed in sequence.

A material of the lower bump portion 31 may be provided up to exposed lateral surface 5x along the pad exposed surface 111 and the lowermost surface 6y of the modified photosensitive layer pattern 6″ (see FIG. 7B). The seed layer 5 may be used as an electrode in an electroplating process to form the lower bump 31.

The upper bump portion 33 may be positioned on the lower bump 31. The lower bump portion 31 electrically connected to the seed layer 5 may be used as an electrode in an electroplating process to form the upper bump portion 33. The upper bump portion 33 may have a pillar shape. The upper bump portion 33 may have a top surface lower than the top surface 61 of the modified photosensitive layer pattern 6″. In some example embodiments, the upper bump portion 33 may have a top surface at a level the same as or higher than that of the top surface 61 of the modified photosensitive layer pattern 6″.

The description above relates to an example in which both of the lower bump portion 31 and the upper bump portion 33 are formed by an electroplating process, but the present inventive concepts are not limited thereto. For example, the lower bump 31 may be formed by an electroplating process, and the upper bump portion 33 may be formed by a different process and then coupled to the lower bump portion 31.

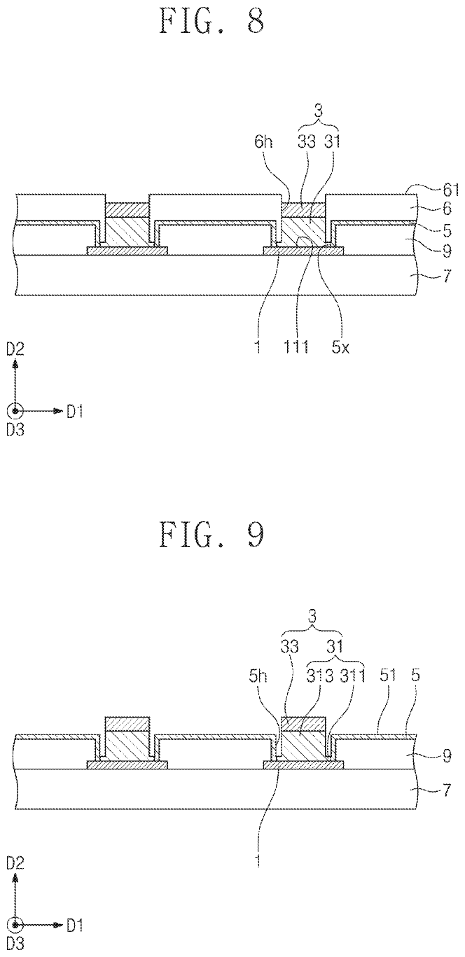

Referring to FIG. 9, the modified photosensitive layer pattern 6″ may be removed at the process S7. The removal of the modified photosensitive layer pattern 6″ may expose a sidewall of the upper bump 33, a sidewall of a pillar portion 313 of the lower bump 31, and/or a top surface of a pedestal portion 311 of the lower bump 31. The removal of the modified photosensitive layer pattern 6″ may also expose the top surface 51 of the seed layer 5.

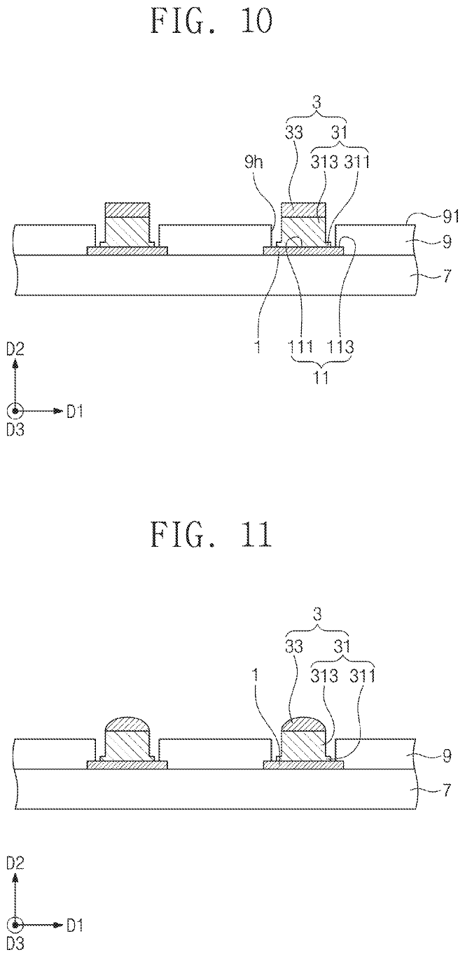

Referring to FIG. 10, the seed layer 5 may be removed at the process S8. The removal of the seed layer 5 may expose the top surface 91 of the dielectric layer 9, the sidewall defining the opening 9h of the dielectric layer 9, and a portion of the pad 1. An etching process may be performed to remove the seed layer 5. In certain example embodiments, the etching process may include a wet etching process. In some example embodiments, the etching process may include a dry etching process.

At the process S8, the bump 3 may have an etch selectivity with respect to the seed layer 5. For example, the bump 3 may not be etched by a material used at the process S8. The material used at the process S8 may selectively etch the seed layer 5.

When the seed layer 5 is removed, a lateral surface of the pedestal portion 311 may also be exposed. Like the exposed lateral surface 5x of the seed layer 5 (see FIG. 7A), the lateral surface of the pedestal portion 311 may be substantially perpendicular to the top surface 11 of the pad 1.

Referring to FIG. 11, at the process S9, an annealing process may be performed to change a shape of the upper bump 33. In certain example embodiments, the annealing process may include a reflow process. The upper bump portion 33 may be changed to have a hemispherical shape. In some example embodiments, the upper bump portion 33 may have various shapes that are easily connected to a substrate, a board, a semiconductor chip, or other components.

In accordance with bump structure fabrication methods according to some example embodiments of the present inventive concepts, because a seed layer is partially removed before an electroplating process is performed, the seed layer may not remain below a bump formed by the electroplating process. Therefore, when an etching process is performed to remove the seed layer remaining after the electroplating process is completed, there may be no need to remove the seed layer remaining below the bump. Thus, no undercut structure may be formed by an etching process to partially remove the seed layer below the bump. Even when a wet etching process is performed, an undercut phenomenon may be avoided. Thus, an actual contact area may be increased between the bump and a pad. The bump may be rigidly coupled to the pad. A mechanical strength may be increased between the bump and the pad. When the bump is subjected to an external force, the bump may not be easily detached from the pad. The bump may be fabricated at higher yield. The bump may be manufactured at lower cost. The bump may improve reliability and increase life span.

Furthermore, because the bump includes a pillar and a pedestal whose cross-sectional area is greater than that of the pillar, the actual contact area may further be increased between the bump and the pad. The bump may thus be more rigidly coupled to the pad. The bump and the pad may be combined with high mechanical strength. In case an external force is applied to the bump, the bump may not be easily separated from the pad.

Further, the bump and the pad may be strongly coupled to each other while reducing an overall size of the bump. Thus, a large number of the bumps may be easily arranged with a relatively fine pitch. Hence, an electronic device may decrease in overall size.

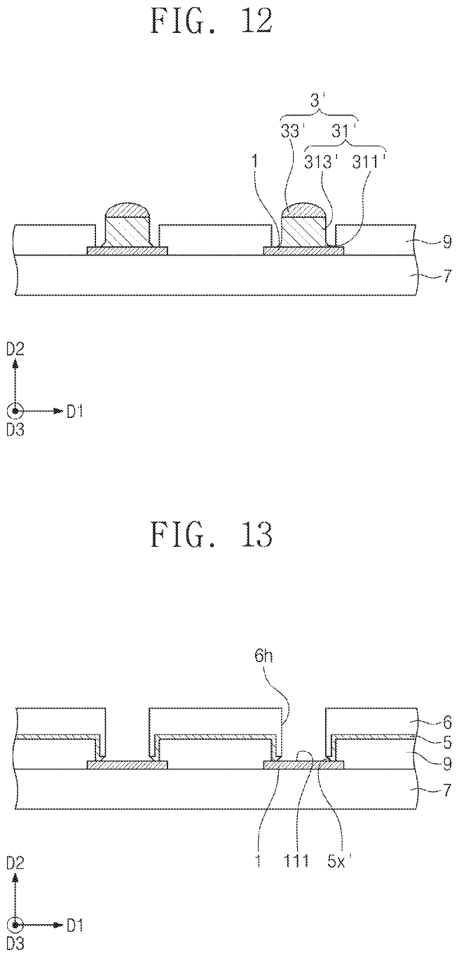

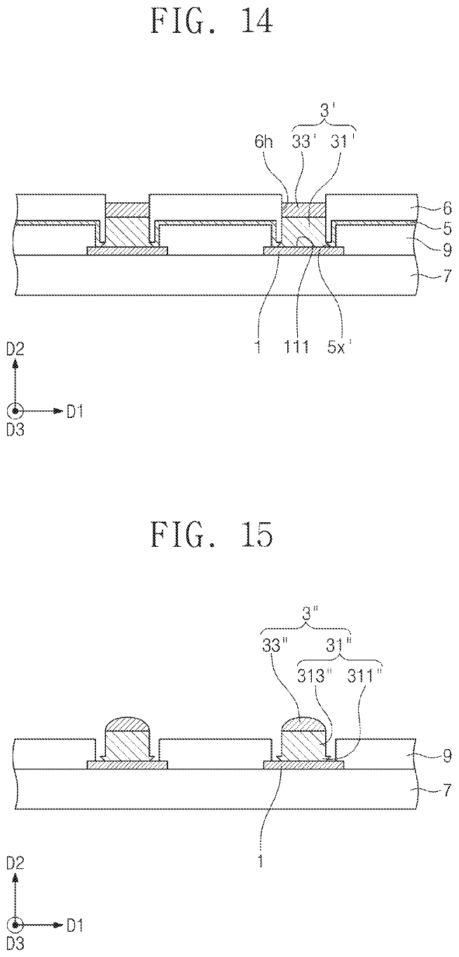

FIG. 12 illustrates a cross-sectional view showing a bump structure according to an example embodiment of the present inventive concepts. FIGS. 13 and 14 illustrate cross-sectional views associated with some processes for forming the bump structure shown in FIG. 12.

In the following description, explanations the same as or substantially similar to those discussed above with reference to FIGS. 1 to 11 will be omitted for convenience of description.

Referring to FIG. 12, a bump 3′ may include a lower bump portion 31′ and an upper bump portion 33′. The lower bump portion 31′ may include a pedestal portion 311′ and a pillar portion 313′.

The pedestal portion 311′ may contact the top surface of the pad 1. The pedestal portion 311′ may connect the pillar portion 313′ to the top surface of the pad 1. The pedestal portion 311′ may have a cross-sectional area in the first direction D1 less than that of the pad 1. In this description, the cross-sectional area of the pedestal portion 311′ may indicate an area of a surface of the pedestal portion 311′ taken along a plane parallel to the first direction D1 and the third direction D3. The cross-sectional area of the pedestal portion 311′ may decrease as approaching the pillar portion 313′ from the pad 1. The pedestal portion 311′ may have a circular shape when viewed in a plan view. The pedestal portion 311′ may have a truncated conical shape. In some example embodiments, the pedestal portion 311′ may have a triangular shape, a rectangular shape, or any other shape when viewed in cross-section in the second direction D2 or taken along a plane parallel to the first direction D1 and the second direction D2.

The pillar portion 313′ may upwardly extend a certain length from the pedestal portion 311′. The pillar portion 313′ and the pedestal portion 311′ may be formed into a single integral body. The pillar portion 313′ may have a height greater than that of the pedestal portion 311′. The pillar portion 313′ may have a cross-sectional area equal to or less than that of the pedestal portion 311′. In this description, the cross-sectional area of the pillar portion 313′ may indicate an area of a surface of the pillar portion 313′ taken along a plane parallel to the first direction D1 and the third direction D3. The pillar portion 313′ and the pedestal portion 311′ may have the same or substantially similar cross-sectional area at a location where the pillar portion 313′ meets the pedestal portion 311′. The pillar portion 313′ may have a circular shape when viewed in a plan view. Thus, the pillar portion 313′ may have a cylindrical shape. In some example embodiments, the pillar portion 313′ may have a triangular shape, a rectangular shape, or any other shape when viewed in cross-section in the second direction D2 or taken along a plane parallel to the first direction D1 and the second direction D2.

The lower bump portion 31′ may include a conductive material. In certain example embodiments, the lower bump portion 31′ may include copper. The present inventive concepts, however, are not limited thereto.

Referring to FIG. 13, at the process S5, a portion of the seed layer 5 on the pad 1 may be removed. An etching process may be performed to remove the portion of the seed layer 5. In certain example embodiments, the etching process may include a wet etching process. The pad exposed surface 111 may be exposed again when the portion of the seed layer 5 on the pad 1 is removed. The partial removal of the seed layer 5 on the pad 1 may expose a lateral surface 5x′ of the seed layer 5. In certain example embodiments, the exposed lateral surface 5x′ may make an acute angle relative to the pad exposed surface 111. A distance between opposing exposed lateral surfaces 5x′ may decrease with increasing distance from the pad exposed surface 111. To achieve this configuration, the etching process may be controlled by its duration time, kind and amount of etching material, or the like.

Referring to FIG. 14, at the process S6, the bump 3′ may be formed on the pad exposed surface 111. The bump 3′ may be formed by an electroplating process in which the seed layer 5 is used as an electrode. In certain example embodiments, an electroplating process may be performed to form the bump 3′, whose material is provided up to the exposed lateral surface 5x′.

Other processes not yet mentioned may be the same as or substantially similar to those discussed above with reference to FIGS. 1 to 11.

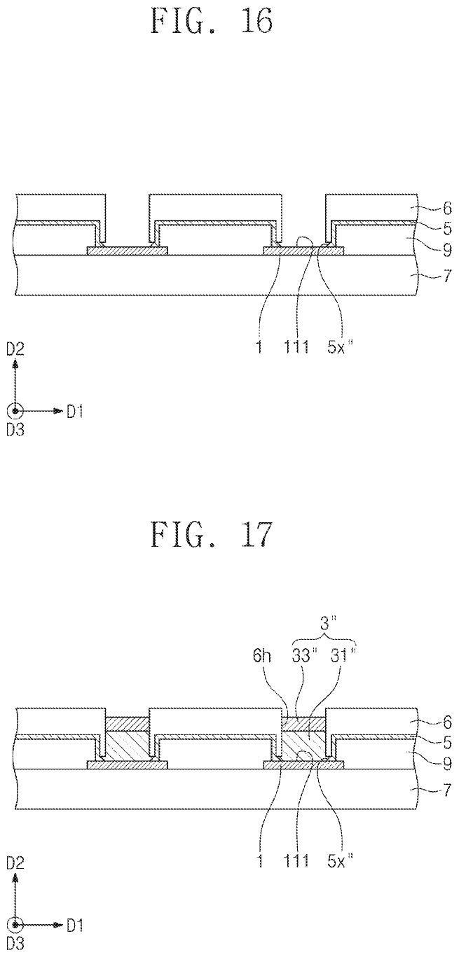

FIG. 15 illustrates a cross-sectional view showing a bump structure according to an example embodiment of the present inventive concepts. FIGS. 16 and 17 illustrate cross-sectional views associated with some processes for forming the bump structure shown in FIG. 15.

In the following description, explanations the same as or substantially similar to those discussed above with reference to FIGS. 1 to 11 will be omitted for convenience of description.

Referring to FIG. 15, a bump 3″ may include a lower bump portion 31″ and an upper bump portion 33″. The lower bump portion 31″ may include a pedestal portion 311″ and a pillar portion 313″.

The pedestal portion 311″ may contact the top surface of the pad 1. The pedestal portion 311″ may upwardly extend from the top surface of the pad 1. The pedestal portion 311″ may have a cross-sectional area less than that of the pad 1. In this description, the cross-sectional area of the pedestal portion 311″ may indicate an area of a surface of the pedestal portion 311″ taken along a plane parallel to the first direction D1 and the third direction D3. The cross-sectional area of the pedestal portion 311″ may increase as approaching the pillar portion 313″ from the pad 1. The pedestal portion 311″ may have a circular shape when viewed in a plan view. The pedestal portion 311″ may have an inverted truncated conical shape. In some example embodiments, the pedestal portion 311″ may have a triangular shape, a rectangular shape, or any other shape when viewed in cross-section in the second direction D2 or taken along a plane parallel to the first direction D1 and the second direction D2.

The pillar portion 313″ may upwardly extend a certain length from the pedestal portion 311″. The pillar portion 313″ and the pedestal portion 311″ may be formed into a single integral body. The pillar portion 313″ may have a height greater than that of the pedestal portion 311″. The pillar portion 313″ may have a cross-sectional area equal to or less than that of the pedestal portion 311″. In this description, the cross-sectional area of the pillar portion 313″ may indicate an area of a surface of the pillar portion 313″ taken along a plane parallel to the first direction D1 and the third direction D3. The pillar portion 313″ may have a circular shape when viewed in a plan view. Thus, the pillar portion 313″ may have a cylindrical shape when. In some example embodiments, the pillar portion 313″ may have a triangular shape, a rectangular shape, or any other shape when viewed in cross-section in the second direction D2 or taken along a plane parallel to the first direction D1 and the second direction D2.

The lower bump portion 31″ may include a conductive material. In certain example embodiments, the lower bump portion 31″ may include copper. The present inventive concepts, however, are not limited thereto.

Referring to FIG. 16, at the process S5, a portion of the seed layer 5 on the pad 1 may be removed. An etching process may be performed to remove the portion of the seed layer 5. In certain example embodiments, the etching process may include a wet etching process. The pad exposed surface 111 may be exposed again when the portion of the seed layer 5 on the pad 1 is removed. The partial removal of the seed layer 5 on the pad 1 may expose a lateral surface 5x″ of the seed layer 5. In certain example embodiments, the exposed lateral surface 5x″ may make an obtuse angle relative to the pad exposed surface 111. A distance between opposing exposed lateral surfaces 5x″ may increase with increasing distance from the pad exposed surface 111. To achieve this configuration, the etching process may be controlled by its duration time, kind and amount of etching material, or the like.

Referring to FIG. 17, at the process S6, the bump 3″ may be formed on the pad exposed surface 111. The bump 3″ may be formed by an electroplating process in which the seed layer 5 is used as an electrode. In certain example embodiments, an electroplating process may be performed to form the bump 3″, whose material is provided up to the exposed lateral surface 5x″.

Other processes not yet mentioned may be the same as or substantially similar to those discussed above with reference to FIGS. 1 to 11.

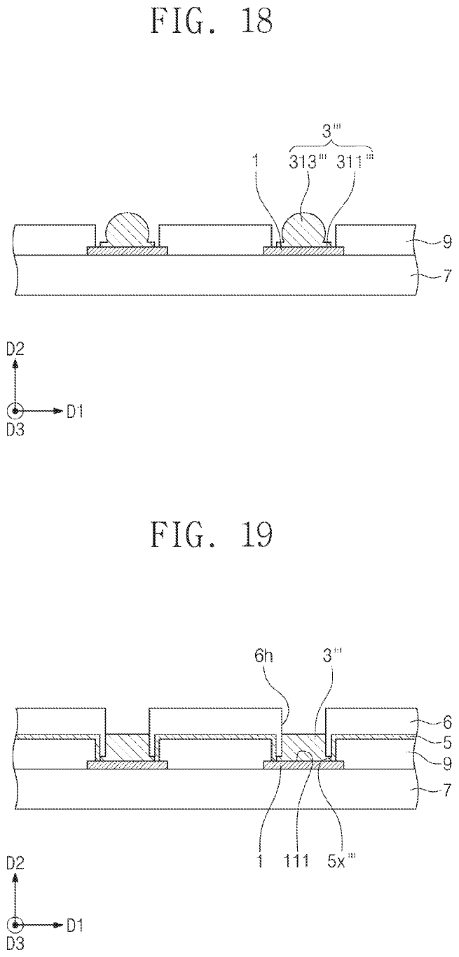

FIG. 18 illustrates a cross-sectional view showing a bump structure according to an example embodiment of the present inventive concepts. FIGS. 19 to 21 illustrate cross-sectional views associated with some processes for forming the bump structure shown in FIG. 18.

In the following description, explanations the same as or substantially similar to those discussed above with reference to FIGS. 1 to 11 will be omitted for convenience of description.

Referring to FIG. 18, a bump 3″′ may include a pedestal portion 311″′ and a body portion 313″′.

The pedestal portion 311″′ may contact the top surface of the pad 1. The pedestal portion 311″′ may upwardly extend from the top surface of the pad 1. The pedestal portion 311″′ may have a cross-sectional area less than that of the pad 1. In this description, the cross-sectional area of the pedestal portion 311″′ may indicate an area of a surface of the pedestal portion 311″′ taken along a plane parallel to the first direction D1 and the third direction D3. The cross-sectional area of the pedestal portion 311″′ may be constant along a direction from the pad 1 to the body portion 313″′. In some example embodiments, the cross-sectional area of the pedestal portion 311″′ may decrease or increase as approaching the body portion 313″′ from the pad 1. The pedestal portion 311″′ may have a circular shape when viewed in a plan view. In some example embodiments, the pedestal portion 311″′ may have a triangular shape, a rectangular shape, or any other shape when viewed in cross-section in the second direction D2 or taken along a plane parallel to the first direction D1 and the second direction D2. The pedestal portion 311′ may include a conductive material. In certain example embodiments, the pedestal portion 311″′ may include solder. The present inventive concepts, however, are not limited thereto.

The body portion 313′ may be formed on a top surface of the pedestal 311″′. In certain example embodiments, the body portion 313′″ may have a truncated spherical shape. The present inventive concepts, however, are not limited thereto. The body portion 313″′ may include a conductive material. In certain example embodiments, the body portion 313″′ may include solder. The body portion 313′ and the pedestal portion 311″′ may be formed into a single integral body.

Referring to FIG. 19, at the process S6, the bump 3″′ may be formed on the pad exposed surface 111. The bump 3″′ may be formed by an electroplating process in which the seed layer 5 is used as an electrode. In certain example embodiments, an electroplating process may be performed to form the bump 3″′, whose material is provided up to the exposed lateral surface 5x″.

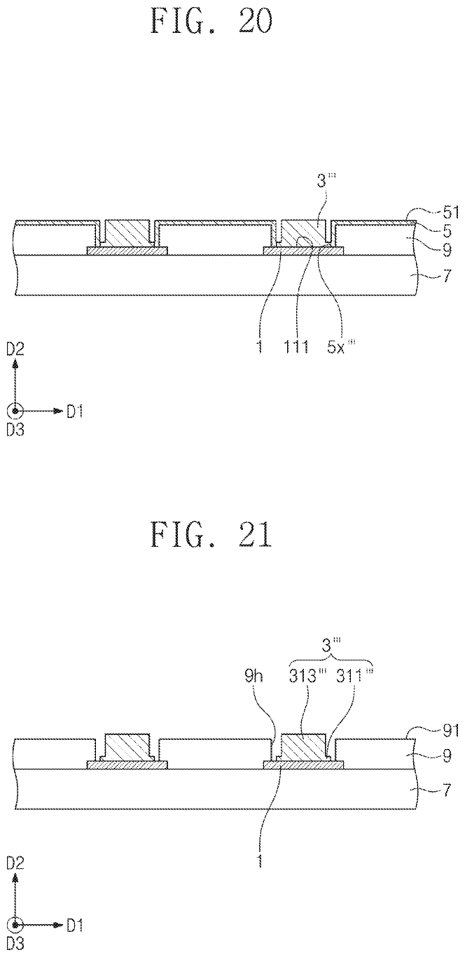

Referring to FIG. 20, the modified photosensitive layer pattern 6″ may be removed at the process S7. The removal of the modified photosensitive layer pattern 6″ may expose a lateral surface of the bump 3″′ and/or a top surface of the pedestal portion 311″′. The removal of the modified photosensitive layer pattern 6″ may also expose the top surface 51 of the seed layer 5.

Referring to FIG. 21, the seed layer 5 may be removed at the process S8. The removal of the seed layer 5 may expose the top surface 91 of the dielectric layer 9, the sidewall defining the opening 9h of the dielectric layer 9, and a portion of the pad 1. An etching process may be performed to remove the seed layer 5. In certain example embodiments, the etching process may include a wet etching process. In some example embodiments, the etching process may include a dry etching process. When the seed layer 5 is removed, a lateral surface of the pedestal portion 311″′ may also be exposed. Like the exposed lateral surface 5x″′ of the seed layer 5 (see FIG. 19), the lateral surface of the pedestal portion 311″′ may be substantially perpendicular to the pad 1.

According to the bump structures and/or the bump structure fabrication methods described above, an undercut phenomenon around the bump structure may be mitigated or avoided due the absence of the seed layer on the bump structure.

A contact area between the bump and the pad may be increased to allow the bump to have improved mechanical performance.

The bump may be provided to have a relatively fine size.

A wet etching process may be used to fabricate the bump structure.

Effects of the present inventive concepts are not limited to the example embodiments mentioned above, other effects which have not been mentioned above will be easily understood to those skilled in the art from the following description.

The two or more processes described herein may not be performed in separate steps, but may be parts of a single process step.

Although the present inventive concepts have been described in connection with some example embodiments described above with the accompanying drawings, it will be understood to those skilled in the art that various changes and modifications may be made without departing from the technical spirit or scope of the present inventive concepts. It therefore will be understood that the disclosed example embodiments described above are just illustrative but not limitative in all aspects.

What is claimed is:

1. A bump structure, comprising:
a pad; and
a bump on a top surface of the pad, the bump including an upper bump portion and a lower bump portion, the lower bump portion including a pedestal portion in contact with the top surface of the pad and a pillar portion upwardly extending from the pedestal portion, a cross-sectional area of at least a portion of the pedestal portion along a first direction being greater than a cross-sectional area of the pillar portion along the first direction.

2. The bump structure of claim 1, wherein the pedestal portion and the pillar portion comprise a same material.

3. The bump structure of claim 1, wherein the cross-sectional area of the at least a portion of the pedestal portion is less than a cross-sectional area of the pad along the first direction.

4. The bump structure of claim 1, wherein the upper bump portion comprises solder and the lower bump portion comprises copper.

5. The bump structure of claim 1, wherein a cross-sectional area of the pedestal portion in the first direction is constant along a second direction perpendicular to the first direction.

6. The bump structure of claim 1, wherein a cross-sectional area of the pedestal portion in the first direction decreases as approaching the pillar portion from the pad.

7. The bump structure of claim 1, wherein a cross-sectional area of the pedestal portion in the first direction increases as approaching the pillar portion from the pad.

8. A bump structure, comprising:
a pad; and
a bump on a top surface of the pad, the bump including a pedestal portion in contact with the pad and a body portion upwardly extending from the pedestal portion, a cross-sectional area of at least a portion of the pedestal portion along a first direction being greater than a cross-sectional area of the body portion along the first direction.

9. The bump structure of claim 8, wherein the pedestal portion and the body portion comprise a same material.

10. The bump structure of claim 8, wherein the bump comprises solder.

11. The bump structure of claim 8, wherein a cross-sectional area of the pedestal portion in the first direction is constant along a second direction perpendicular to the first direction.

12. The bump structure of claim 8, wherein a cross-sectional area of the pedestal portion in the first direction decreases as approaching the body portion from the pad.

13. The bump structure of claim 8, wherein a cross-sectional area of the pedestal portion in the first direction increases as approaching the body portion from the pad.

14. A bump structure fabrication method comprising:
preparing an electronic device having a pad thereon;
forming a seed layer on the pad;
forming a photosensitive layer pattern on the seed layer to expose a portion of the seed layer;
removing the exposed portion of the seed layer to expose a portion of the pad; and
forming a bump on the exposed portion of the pad.

15. The bump structure fabrication method of claim 14, further comprising:
removing the photosensitive layer pattern; and
removing a remaining portion of the seed layer.

16. The bump structure fabrication method of claim 15, wherein the removing a remaining portion of the seed layer comprises performing a wet etching process.

17. The bump structure fabrication method of claim 14, wherein
the removing comprises removing the seed layer to expose a lateral surface of the seed layer, and
the exposed lateral surface of the seed layer is not at a same plane as a lateral surface of the photosensitive layer pattern.

18. The bump structure fabrication method of claim 17, where the forming a bump comprises performing an electroplating process such that a material of the bump is provided up to the exposed lateral surface of the seed layer.

19. The bump structure fabrication method of claim 14, wherein the removing the exposed portion of the seed layer comprises performing an etching process.

20. The bump structure fabrication method of claim 14, wherein the forming a photosensitive layer pattern comprises performing exposure and development processes.
